(19) United States
(12) Patent Application Publication
(10) Pub. No.: US 2025/0185181 A1
(43) Pub. Date: Jun. 5, 2025

(54) METHOD FOR PLATING EDGE CONNECTORS ON CIRCUIT BOARD WITH GOLD, AND CIRCUIT BOARD

(71) Applicant: SUZHOU METABRAIN INTELLIGENT TECHNOLOGY CO., LTD., Suzhou, Jiangsu (CN)

(72) Inventors: Fengyue CHEN, Suzhou, Jiangsu (CN); Xiaotong MAO, Suzhou, Jiangsu (CN)

(21) Appl. No.: 18/724,650

(22) PCT Filed: Feb. 20, 2023
(86) PCT No.: PCT/CN2023/077152

§ 371 Date: Jun. 27, 2024

(30) Foreign Application Priority Data
Aug. 25, 2022 (CN) 202211022792.3

(51) Int. Cl. H05K 3/40; C23C 18/16; C23C 18/42; C25D 5/54; C25D 7/00; C25D 13/02; C25D 13/12; C25D 21/12

(52) U.S. Cl. CPC H05K 3/403; C23C 18/1646; C23C 18/1675; C23C 18/42; C25D 5/54; C25D 7/00; C25D 13/02; C25D 13/12; C25D 21/12

(57) ABSTRACT

The present application relates to the processing field of circuit boards. Disclosed are a method for plating edge connectors on a circuit board with gold, and a circuit board. The method comprises the following steps: filling gaps between edge connectors on a circuit board with a conductive medium, wherein the height of the conductive medium is greater than the height of each edge connector; enabling a tip of a first probe to be tangent to an upper surface of the conductive medium, and placing a tip of a second probe above the edge connector, wherein the tip of the second probe and the tip of the first probe are located in the same horizontal plane; connecting the first probe and the second probe to a loop on/off detection device; plating an upper surface of the edge connector with gold, and stopping gold plating when the loop on/off detection device detects the connection of a loop; and removing the conductive medium. In the present application, the gaps between the edge connectors are filled with the conductive medium, the height of which is greater than that of the edge connector, the tip of the first probe is tangent to the upper surface of the conductive medium, the tip of the second probe is flush with the tip of the first probe, and gold plating is stopped when each gold-plated layer comes into contact with the tip of the second probe, such that the gold-plated layers on all the edge connectors are equal in thickness; and there is no need to manufacture a lead wire.

### CROSS-REFERENCE TO RELATED APPLICATION

The application claims priority to Chinese patent application No. 202211022792.3, titled “GOLD PLATING METHOD FOR CONNECTING FINGERS OF CIRCUIT BOARD, AND CIRCUIT BOARD”, filed on Aug. 25, 2022 before the China National Intellectual Property Administration, which is incorporated herein in its entirety by reference.

### TECHNICAL FIELD

The disclosure relates to the technical field of circuit board processing, and more particularly relates to a gold plating method for connecting fingers of a circuit board, and the circuit board.

### BACKGROUND

In the fabrication of printed circuit boards (PCBs), connecting fingers on the PCBs need to be gold-plated. At present, a technological process of plating the connecting fingers with gold is generally as follows: fabrication of lines (including lead wires for communicating the connecting fingers)→solder mask→gold plating→drying film→removal of the lead wires remained on the PCB. The gold plating is carried out by means of electrophoresis. There are two ways to remove the lead wires, among them, the first way is to cut off the lead wires by mechanical bevelers, and the second way is to remove the lead wires by means of etching, that is, exposing parts of the lead wire to an etching solution, and covering other parts with anti-corrosive films, thereby etching away the lead wire.

### SUMMARY

An object of the disclosure is to provide a gold plating method for connecting fingers of a circuit board, and the circuit board.

In order to solve the above technical problem, the disclosure provides a gold plating method for connecting fingers of a circuit board, including:
filling gaps among the connecting fingers on the circuit board with a conductive medium, a height of the conductive medium being greater than a height of the connecting fingers;
placing a tip of a first probe to be tangent to an upper surface of the conductive medium, and placing a tip of a second probe above the connecting fingers, the tip of the second probe and the tip of the first probe are positioned on a same horizontal plane, and the first probe and the second probe are connected to a loop on-off detection device;
performing gold plating on upper surfaces of the connecting fingers, and stopping gold plating in response to detecting by the loop on-off detection device that a loop is conducted; and
removing the conductive medium.

In some embodiments, the filling gaps among the connecting fingers on the circuit board with a conductive medium includes filling the gaps among the connecting fingers on the circuit board with graphite.

In some embodiments, the removing the conductive medium includes rinsing off the graphite.

In some embodiments, the filling the gaps among the connecting fingers on the circuit board with graphite includes: filling the gaps among the connecting fingers on the circuit board with the graphite by means of spraying.

In some embodiments, the filling gaps among the connecting fingers on the circuit board with a conductive medium includes: forming metal blocks in the gaps among the connecting fingers on the circuit board.

In some embodiments, prior to filling the gaps among the connecting fingers on the circuit board with the conductive medium, the method further includes fabricating a non-gold conductive layer on the upper surfaces of the connecting fingers; accordingly, a height of the conductive medium being greater than a height of the connecting fingers includes: the height of the conductive medium being greater than the height of the connecting fingers and the non-gold conductive layer.

In some embodiments, the step of fabricating a non-gold conductive layer on the upper surfaces of the connecting fingers includes: fabricating a copper layer, a nickel layer or a silver layer on the upper surfaces of the connecting fingers.

In some embodiments, the step of fabricating a copper layer, a nickel layer or a silver layer on the upper surfaces of the connecting fingers includes: fabricating the copper layer, the nickel layer or the silver layer on the upper surfaces of the connecting fingers by means of electroplating.

In some embodiments, the step of fabricating a non-gold conductive layer on the upper surfaces of the connecting fingers includes: fabricating a non-metallic conductive layer on the upper surfaces of the connecting fingers.

In some embodiments, a height difference between the upper surface of the conductive medium and the upper surfaces of the non-gold conductive layer is 0.514 mil.

In some embodiments, the height of the first probe is the same as the height of the second probe.

In some embodiments, the step of performing gold plating on upper surfaces of the connecting fingers includes: performing gold plating on the upper surfaces of the connecting fingers by means of electroplating.

In some embodiments, in response to detecting by the loop on-off detection device that the loop is conducted, the method further includes sending alarm prompt information by the loop on-off detection device.

The present disclosure further provides a circuit board, and connecting fingers on the circuit board are gold plated by adopting any of the gold plating methods for connecting fingers of a circuit board described above.

### BRIEF DESCRIPTION OF THE DRAWINGS

In order to explain technical solutions of embodiments of the disclosure or the related art more clearly, a brief introduction will be given to accompanying drawings to be used in the description of the embodiments or the related art. Apparently, the accompanying drawings in the following description are only intended for some embodiments of the disclosure, and for those skilled in the art, other accompanying drawings may be obtained according to these accompanying drawings without involving any creative effort.

FIG. 1 is a schematic diagram of a circuit board with lines being fabricated;

FIG. 2 is a schematic diagram of cutting lead wires when the lead wires are cut off by adopting mechanical beveler in the related art;

FIG. 3 is a schematic diagram of gold suspension caused by excessive etching when the lead wires are removed by means of etching in the related art;

FIG. 4 is a flowchart of a gold plating method for connecting fingers of a circuit board provided by an embodiment of the disclosure;

FIG. 5 is a top view of a circuit board with conductive medium being filled in gaps among the connecting fingers provided by an embodiment of the disclosure;

FIG. 6 is a front view of a circuit board with conductive medium being filled in gaps among the connecting fingers provided by an embodiment of the disclosure;

FIG. 7 is a schematic diagram illustrating fixing probes on the conductive medium and the connecting fingers in an embodiment of the disclosure;

FIG. 8 is a flowchart of another gold plating method for connecting fingers of a circuit board provided by an embodiment of the disclosure;

FIG. 9 is a flowchart of another gold plating method for connecting fingers of a circuit board provided by an embodiment of the disclosure;

FIG. 10 is a flowchart of another gold plating method for connecting fingers of a circuit board provided by an embodiment of the disclosure; and

FIG. 11 is a flowchart of another gold plating method for connecting fingers of a circuit board provided by an embodiment of the disclosure.

### DETAILED DESCRIPTION

In order that those skilled in the art may better understand the solution of the disclosure, a further detailed description of the disclosure is provided below in connection with the accompanying drawings and specific embodiments. Apparently, only some embodiments rather than all embodiments are described. Based on the embodiments in the disclosure, all other embodiments obtained by those skilled in the art without involving any creative effort shall fall within the protection scope of the disclosure.

In the following description, numerous specific details are set forth in order to provide a thorough understanding of the disclosure, but the disclosure may be implemented in other ways than described herein. Those skilled in the art may make similar expansions without departing from the connotation of the disclosure, and thus the disclosure is not limited to the specific examples disclosed below.

As described in the section of background, at present, a technological process of plating connecting fingers with gold is generally as follows: fabrication of lines (including lead wires for communicating the connecting fingers)→solder mask→gold plating→drying film→removal of the lead wires remained on the PCB. There are two ways to remove the lead wires, among them, the first way is to cut off the lead wires by mechanical bevelers, and the second way is to remove the lead wires by means of etching, that is, exposing parts of the lead wire to an etching solution, and covering other parts with anti-corrosive films, thereby etching away the lead wire. The lead wires refer to conducting wires that interconnect the connecting fingers together during fabrication of the connecting fingers.

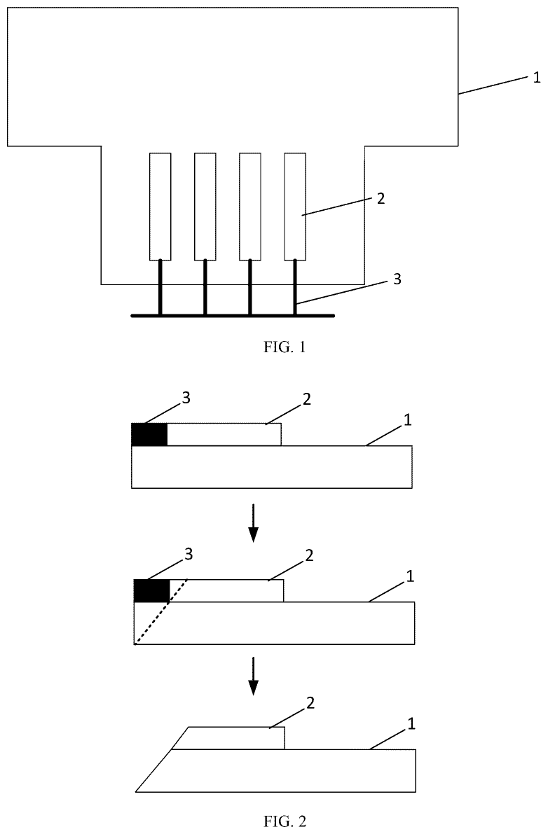

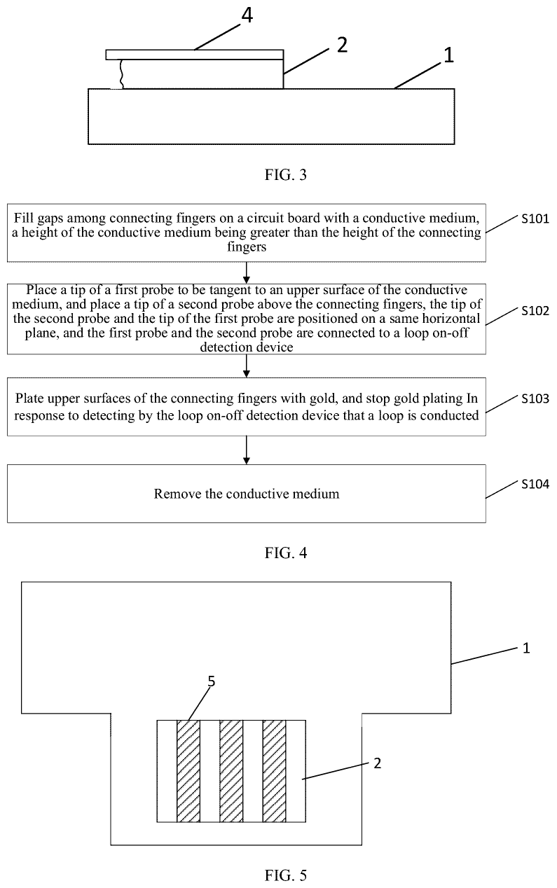

A schematic diagram of a circuit board with lines being fabricated is shown in FIG. 1, each connecting finger 2 on the circuit board 1 is connected to a lead wire 3, and then all the lead wires 3 are connected and conducted via another lead wire 3. When the lead wires 3 are cut off by adopting mechanical bevelers, a schematic diagram of cutting is shown in FIG. 2, and by means of cutting, burrs and debris are likely to leave on edges of the connecting fingers, thereby resulting in short circuit. Moreover, the means of cutting is not applicable to connecting fingers with unequal lengths. When the lead wires 3 are removed by means of etching, a situation of gold suspension caused by excessive etching may occur, that is, a part of gold plated layer 4 is suspended, as shown in FIG. 3. In gold plating, a thickness for gold plating is controlled by controlling time of electrophoresis and a concentration of gold ions. However, as an electroplating process proceeds, the concentration of the gold ions may gradually decrease and cannot be accurately controlled in real time, resulting in non-uniform thickness for gold plating.

An existing gold plating method for connecting fingers has defects below. Firstly, a thickness for gold plating is controlled by controlling time of electrophoresis and a concentration of gold ions; however, as an electroplating process proceeds, the concentration of the gold ions may gradually decrease and cannot be accurately controlled in real time, resulting in non-uniform thickness for gold plating. Secondly, when the lead wires are removed by means of cutting, burrs and debris are likely to leave on edges of the connecting fingers, thereby resulting in short circuit, and this method is only applicable to connecting fingers with equal lengths, rather than connecting fingers with unequal lengths. Thirdly, when the lead wires are removed by means of etching, a situation of gold suspension caused by excessive etching may occur, resulting in unsmooth pulling and inserting of the connecting fingers.

In view of the above, the disclosure provides a gold plating method for connecting fingers of a circuit board. Referring to FIG. 4, the method includes steps described below.

At step S101, gaps among the connecting fingers on the circuit board are filled with a conductive medium, and a height of the conductive medium is greater than the height of the connecting fingers.

The connecting fingers consist of a plurality of golden conductive contact pads, the surface of which is plated with gold and are arranged like fingers. The connecting fingers have the characteristics of extremely high oxidation resistance, good wear resistance and high conductivity.

A plurality of connecting fingers are disposed on the circuit board, and a length relationship among all the connecting fingers on the circuit board is not limited in the disclosure. In some embodiments, all the connecting fingers on the circuit board may have equal or unequal lengths. There are various cases for the connecting fingers with unequal lengths, for example, the lengths of all the connecting fingers are unequal, or the lengths of a part of the connecting fingers are equal, and the lengths of these connecting fingers are not equal to the lengths of other connecting fingers, and the like.

It should be noted that the conductive medium is not specifically limited in the disclosure, as long as the conductive medium has a conductive property and may be in contact and conduction with the connecting fingers. Materials that may be selected as the conductive medium will be described in the following examples, and reference may be made to the following examples for details.

To ensure good contact between the conductive medium and side surfaces of the connecting fingers, gaps among the connecting fingers are filled with the conductive medium.

When the gaps among the connecting fingers are filled with the conductive medium, all the gaps among the connecting fingers may be filled with the conductive medium, or only one gap between the connecting fingers may be filled with the conductive medium, or the gaps among some of the connecting fingers may be filled with the conductive medium, and the gaps among other connecting fingers may be not filled with the conductive medium, which are all within the protection scope of the disclosure.

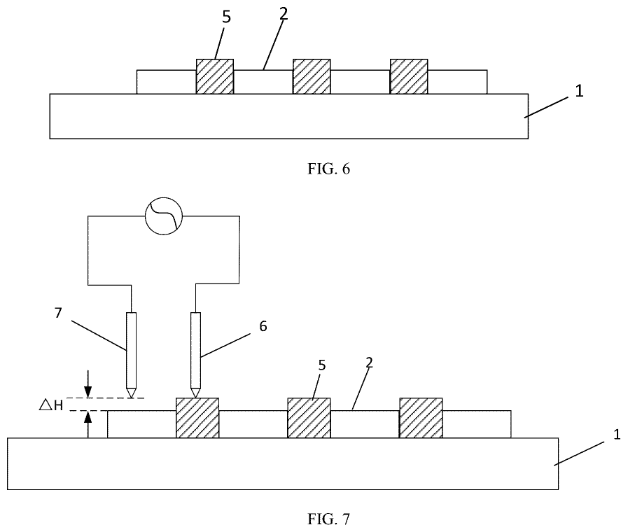

For example, a quantity of the connecting fingers is four, and all the gaps among the connecting fingers are filled with the conductive medium. After the gaps among the connecting fingers 2 are filled with the conductive medium 5, a top view of the circuit board 1 is shown in FIG. 5, and a front view of the circuit board 1 is shown in FIG. 6.

It should also be noted that a difference between the height of the conductive medium and the height of the connecting finger is not limited in the disclosure, and may be set according to the thickness for gold plating on surface of the connecting finger. For example, a height difference between an upper surface of the conductive medium and the upper surface of the connecting finger is 0.514 mil, or any other height difference.

In this step, the upper surface of the connecting finger is not provided with other plated layers, but is directly plated with gold. That is, a difference between the height of the conductive medium and the height of the connecting finger is the thickness for gold plating.

At step S102, a tip of a first probe is disposed to be tangent to the upper surface of the conductive medium, a tip of a second probe is placed above the connecting fingers, and the tip of the second probe and the tip of the first probe are positioned on a same horizontal plane. The first probe and the second probe are connected to a loop on-off detection device.

The first probe and the second probe are respectively connected to the loop on-off detection device via conducting wires. In some embodiments, as some feasible implementations, the first probe and the second probe have the same height. However, this is not specifically limited in the disclosure, and as other feasible implementations, the first probe and the second probe have unequal heights, for example, the height of the first probe is greater than that of the second probe, or the height of the second probe is greater than that of the first probe. The heights of the first probe and the second probe are lengths of the first probe and the second probe.

In some embodiments, the first probe and the second probe have the same height. In this case, the tip of the first probe and the tip of the second probe may be positioned on the same horizontal plane by controlling ends of the first probe and the second probe away from the tips to be positioned on the same horizontal plane. In this way, the tip of the first probe and the tip of the second probe may be positioned on the same horizontal plane conveniently and quickly without directly detecting positions of the tip of the first probe and the tip of the second probe. When the first probe and the second probe have unequal heights, it is necessary to observe or detect whether the tip of the first probe and the tip of the second probe are positioned on the same horizontal plane. If the tip of the first probe and the tip of the second probe are not positioned on the same horizontal plane, it is necessary to adjust the position of the tip of the second probe until the tip of the first probe and the tip of the second probe are positioned on the same horizontal plane.

The tip of the first probe is tangential to the upper surface of the conductive medium, in other words, the tip of the first probe is in contact with the upper surface of the conductive medium. The tip of the second probe is placed above the connecting fingers, and positioned on the same horizontal plane with the tip of the first probe. As the height of the conductive medium is greater than height of the connecting fingers, a certain distance exists between the tip of the second probe and the upper surface of the connecting fingers. The distance between the tip of the second probe and the upper surface of the connecting fingers is the height difference between the upper surface of the conductive medium and the upper surface of the connecting fingers.

Taking the case in which the first probe 6 and the second probe 7 have the same height as an example, a schematic diagram in which the first probe 6 and the second probe 7 connected to the loop on-off detection device are respectively fixed on the conductive medium 5 and the connecting fingers 2 is shown in FIG. 7. The height difference between the tip of the second probe 7 and the connecting fingers 2 is AH. The second probe 7 needs to be placed above only one connecting finger 2. The connecting finger 2 above which the second probe 7 is placed may be the connecting finger 2 adjacent to the conductive medium 5 in contact with the tip of the first probe 6, as shown in FIG. 7, or may be the connecting finger 2 spaced apart from the conductive medium 5 in contact with the tip of the first probe 6, which are both within the protection scope of the disclosure.

At step S103, gold plating is performed on the upper surface of the connecting fingers, and gold plating is stopped in response to detecting by the loop on-off detection device that the loop is conducted.

It should be noted that while gold plating, all the connecting fingers are plated with gold simultaneously.

As shown in FIG. 7, the loop refers to a loop formed among the second probe 7, the connecting finger 2, the conductive medium 5, the first probe 6, a conducting wire for connecting the loop on-off detection device to the first probe 6, the loop on-off detection device, a conducting wire for connecting the loop on-off detection device to the second probe 7, and the second probe 7.

As gold plating on the surface of the connecting fingers 2 proceeds, the distance between the tip of the second probe 7 and the upper surface of the connecting fingers 2 gradually decreases. When the thickness for gold plating on the upper surface of the connecting fingers 2 is equal to the height difference between the upper surface of the conductive medium 5 and the upper surface of the connecting fingers 2, the tip of the second probe 7 is in contact with the gold plated layer, and at this moment, the loop is conducted. The thickness for gold plating on all the connecting fingers 2 is equal, which is the height difference between the upper surface of the conductive medium 5 and the upper surface of the connecting fingers 2, so as to achieve the purpose of controlling the thickness of the gold plated layer with high precision.

At step S104, the conductive medium is removed.

The manner of removing the conductive medium may depend on the specific material of the conductive medium, which is not limited in the disclosure.

After removing the conductive medium, the connecting fingers of the circuit board are plated with gold layers with equal thickness.

According to the gold plating method of the disclosure, the gaps among the connecting fingers are filled with the conductive medium to enable the connecting fingers to be mutually conducted, the conductive medium may be directly removed after the connecting fingers are plated with gold. In this way, it is not necessary to fabricate lead wires for communicating the connecting fingers, thus the problems in the related art, that burrs and debris are left on edges of the connecting fingers when the lead wires are cut off and the connecting fingers are unsmooth in inserting and pulling due to gold suspension caused by excessive etching, are avoided, and the problem of residual lead wires is avoided simultaneously. Moreover, since there is no need for fabricating and removing the lead wires, the method of the disclosure may shorten the processing procedure of plating the connecting fingers with gold, and save the process cost. In addition, in the disclosure, when the upper surface of the connecting fingers is plated with gold, the tip of the first probe is tangent to the upper surface of the conductive medium, the second probe is placed above the connecting fingers, the distance between the tip of the second probe and the upper surface of the connecting fingers is the height difference between the conductive medium and the connecting fingers, a loop is formed by the connecting fingers, the conductive medium, the first probe, the second probe and the loop on-off detection device. When the gold plated layer on the upper surface of the connecting fingers is in contact with the tip of the second probe, the loop is conducted and the gold plating is finished, so that thicknesses of the gold plated layer on all the connecting fingers are equal, thereby achieving accurate control of the thickness for gold plating, and saving raw materials. Furthermore, the gold plating method of the disclosure is not limited by a length relationship of the connecting fingers, and is applicable to connecting fingers with unequal lengths and connecting fingers with equal lengths. Therefore, the gold plating method of the disclosure has a wide application range.

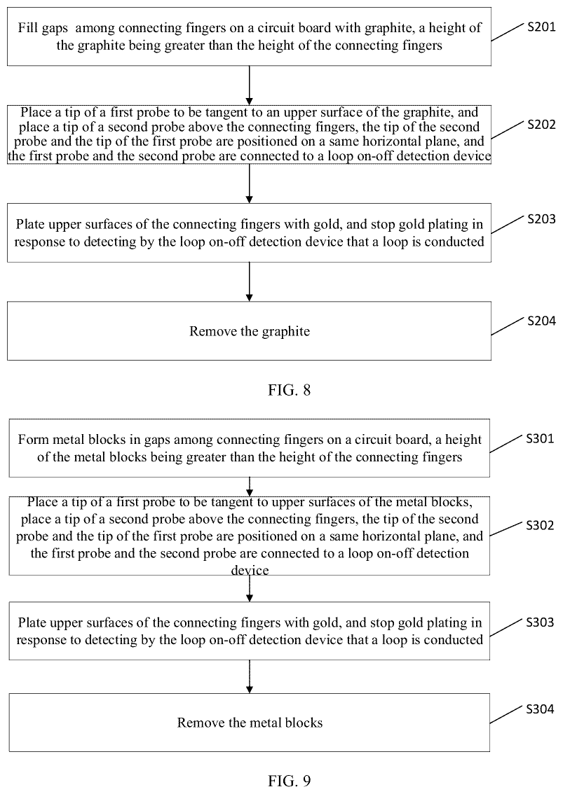

On the basis of the above embodiment, in some embodiments of the disclosure, referring to FIG. 8, the gold plating method for the connecting fingers of the circuit board includes steps below.

At step S201, the gaps among the connecting fingers on the circuit board are filled with graphite, and a height of the graphite is greater than the height of the connecting fingers.

In this embodiment, the conductive medium filled in the gaps among the connecting fingers is graphite. Since the graphite material has good corrosion resistance and electrical conductivity, and is stable in performance and high in reliability, the connecting fingers may be mutually conducted by filling the graphite in the gaps among all the connecting fingers.

In some embodiments, the gaps among the connecting fingers on the circuit board are filled with graphite by:
filling the gaps among the connecting fingers on the circuit board with the graphite by means of spraying.

The circuit board with the connecting fingers is fixed on an ink jet device, and the graphite material is sprayed into the gaps among the connecting fingers. The gaps among the connecting fingers are filled with the graphite by means of spraying, so that the flatness of the upper surface of the graphite may be high.

The height difference between the upper surface of the graphite and the upper surfaces of the connecting fingers is the thickness of the gold plated layer. Accordingly, the accurate control of the thicknesses of the gold plated layer on the surfaces of the connecting fingers is achieved by controlling the height of the graphite and the height of the connecting fingers in the disclosure. The tip of the second probe needs to be kept on the same horizontal plane with the tip of the first probe. When the tip of the first probe is in contact with the upper surface of the graphite and the second probe is placed above the connecting fingers, as the upper surface of the graphite has good flatness, no matter which position on the upper surface of the graphite is in contact with the tip of the first probe, distances between the tip of the first probe and the upper surfaces of the connecting fingers may be equal, so as to ensure that the thickness of the actual gold plated layer is the required thickness of the gold plated layer, and improve the accuracy of the thickness of the gold plated layer.

At step S202, the tip of the first probe is placed to be tangent to the upper surface of the graphite, the tip of the second probe is placed above the connecting fingers, and the tip of the second probe and the tip of the first probe are positioned on the same horizontal plane. The first probe and the second probe are connected to the loop on-off detection device.

The tip of the first probe is tangent to the upper surface of the graphite, the tip of the second probe is placed above the connecting fingers, and positioned on the same horizontal plane with the tip of the first probe. Since the height of the graphite is greater than the height of the connecting fingers, a certain distance exists between the tip of the second probe and the upper surfaces of the connecting fingers. The distance between the tip of the second probe and the upper surfaces of the connecting fingers is the height difference between the upper surface of the graphite and the upper surfaces of the connecting fingers.

The first probe and the second probe are respectively connected to the loop on-off detection device via conducting wires. In some embodiments, as some feasible implementations, the first probe and the second probe have the same height. However, this is not specifically limited in the disclosure, and as other feasible implementations, the first probe and the second probe have unequal heights, for example, the height of the first probe is greater than that of the second probe, or the height of the second probe is greater than that of the first probe. The heights of the first probe and the second probe are lengths of the first probe and the second probe.

In some embodiments, the first probe and the second probe have the same height. In this case, the tip of the first probe and the tip of the second probe may be positioned on the same horizontal plane by controlling ends of the first probe and the second probe away from the tips to be positioned on the same horizontal plane. In this way, the tip of the first probe and the tip of the second probe may be positioned on the same horizontal plane conveniently and quickly without directly detecting positions of the tip of the first probe and the tip of the second probe. When the first probe and the second probe have unequal heights, it is necessary to observe or detect whether the tip of the first probe and the tip of the second probe are positioned on the same horizontal plane. If the tip of the first probe and the tip of the second probe are not positioned on the same horizontal plane, it is necessary to adjust the position of the tip of the second probe until the tip of the first probe and the tip of the second probe are positioned on the same horizontal plane.

At step S203, gold plating is performed on the upper surfaces of the connecting fingers, and gold plating is stopped in response to detecting by the loop on-off detection device that the loop is conducted.

As gold plating proceeds, when the upper surface of the gold plated layer is flush with the upper surface of the graphite, the tip of the second probe is in contact with the gold plated layer, and the loop is conducted. The thickness for gold plating on all the connecting fingers is equal, which is the height difference between the upper surface of the graphite and the upper surfaces of the connecting fingers, so as to achieve the purpose of controlling the thicknesses of the gold plated layers with high precision.

At step S204, the graphite is removed.

When the conductive medium is the graphite, the conductive medium is removed as follows:
rinsing off the graphite in a very simple and quick manner, and water or other types of liquid may be used as a medium for rinsing, which is not specifically limited in the disclosure.

On the basis of the above embodiments, in some embodiments of the disclosure, referring to FIG. 9, the gold plating method for the connecting fingers of the circuit board includes steps below.

At step S301, metal blocks are formed in the gaps among the connecting fingers on the circuit board, and a height of the metal blocks is greater than the height of the connecting fingers.

Materials of the metal blocks include, but are not limited to, copper, silver, gold, and nickel.

In order to ensure a good contact between the metal blocks and adjacent connecting fingers, when the metal blocks are formed in the gaps among the connecting fingers, the materials of the metal blocks may be melted first, and the materials of the metal blocks in a molten state have good fluidity. When the materials of the metal blocks in the molten state are disposed in the gaps among the connecting fingers, shapes of the metal blocks may be easily changed, so that the good contact between the metal blocks and the connecting fingers may be achieved, thereby ensuring that the loop is conducted when the gold plated layer is in contact with the tip of the second probe, the gold plating is stopped. In this way, the accurate control of the thickness of the gold plated layer is achieved.

At step S302, the tip of the first probe is placed to be tangent to upper surfaces of the metal blocks, the tip of the second probe are placed above the connecting fingers, and the tip of the second probe and the tip of the first probe are positioned on the same horizontal plane. The first probe and the second probe are connected to the loop on-off detection device.

The tip of the first probe is tangent to the upper surfaces of the metal blocks, and the tip of the second probe is placed above the connecting fingers, and positioned on the same horizontal plane with the tip of the first probe. Since the height of the metal blocks is greater than height of the connecting fingers, a certain distance exists between the tip of the second probe and the upper surfaces of the connecting fingers. The distance between the tip of the second probe and the upper surfaces of the connecting fingers is the height difference between the upper surfaces of the metal blocks and the upper surfaces of the connecting fingers.

The first probe and the second probe are respectively connected to the loop on-off detection device via conducting wires. In some embodiments, as some feasible implementations, the first probe and the second probe have the same height. However, this is not specifically limited in the disclosure, and as other feasible implementations, the first probe and the second probe have unequal heights, for example, the height of the first probe is greater than that of the second probe, or the height of the second probe is greater than that of the first probe. The heights of the first probe and the second probe are lengths of the first probe and the second probe.

In some embodiments, the first probe and the second probe have the same height. In this case, the tip of the first probe and the tip of the second probe may be positioned on the same horizontal plane by controlling ends of the first probe and the second probe away from the tips to be positioned on the same horizontal plane. In this way, the tip of the first probe and the tip of the second probe may be positioned on the same horizontal plane conveniently and quickly without directly detecting positions of the tip of the first probe and the tip of the second probe. When the first probe and the second probe have unequal heights, it is necessary to observe or detect whether the tip of the first probe and the tip of the second probe are positioned on the same horizontal plane.

If the tip of the first probe and the tip of the second probe are not positioned on the same horizontal plane, it is necessary to adjust the position of the tip of the second probe until the tip of the first probe and the tip of the second probe are positioned on the same horizontal plane.

At step S303, gold plating is performed on the upper surfaces of the connecting fingers, and gold plating is stopped in response to detecting by the loop on-off detection device that a loop is conducted.

As gold plating proceeds, when the upper surface of the gold plated layer is flush with the upper surfaces of the metal blocks, the tip of the second probe is in contact with the gold plated layer, and the loop is conducted. The thickness for gold plating on all the connecting fingers is equal, which is the height difference between the upper surfaces of the metal blocks and the upper surfaces of the connecting fingers, so as to achieve the purpose of controlling the thicknesses of the gold plated layers with high precision.

At step S304, the metal blocks are removed.

It should be noted that the manner of removing the metal blocks is not limited in the disclosure, which depends on the circumstances. For example, the metal blocks positioned in the gaps among the connecting fingers may be removed by means of wet etching.

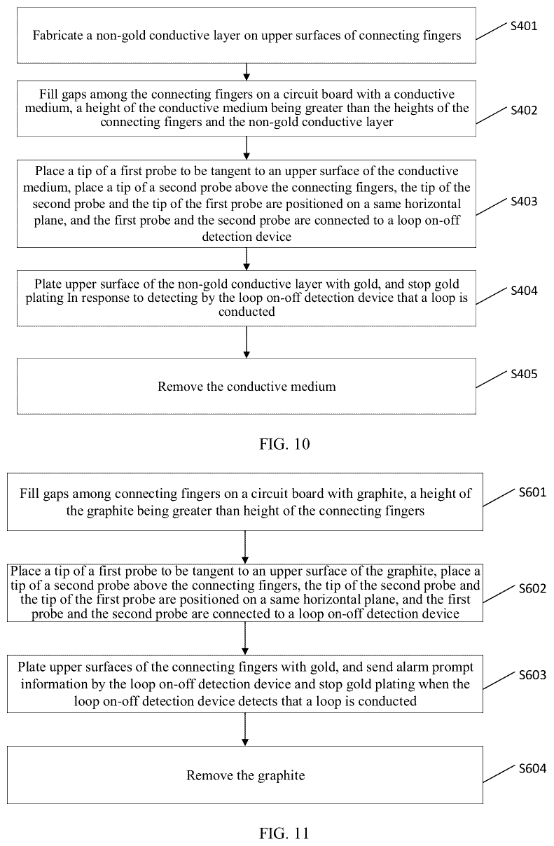

Referring to FIG. 10, on the basis of any one of the above embodiments, in some embodiments of the disclosure, the gold plating method for the connecting fingers of the circuit board includes steps below.

At step S401, a non-gold conductive layer is fabricated on the upper surfaces of the connecting fingers.

Materials of the non-gold conductive layer may be materials with a lower price than gold, and metallic materials or non-metallic conductive materials may be selected. The type of the metallic material may be selected according to actual circumstances, which is not specifically limited in the disclosure. Further, the thickness of the non-gold conductive layer is also not specifically limited in the disclosure, which depends on the circumstances.

As some feasible implementations, the fabrication of the non-gold conductive layer on the upper surfaces of the connecting fingers includes: fabricating a copper layer on the upper surfaces of the connecting fingers. The manner of fabricating the copper layer on the upper surfaces of the connecting fingers is not specifically limited in the disclosure, and may be selected voluntarily. In some embodiments, the fabrication of the copper layer on the upper surfaces of the connecting fingers includes: fabricating the copper layer on the upper surfaces of the connecting fingers by means of electroplating. By fabricating the copper layer by means of electroplating, thickness uniformity of the copper layer is good, thereby improving the flatness of surfaces of gold layer.

As other feasible implementations, the fabrication of the non-gold conductive layer on the upper surfaces of the connecting fingers includes: fabricating a nickel layer on the upper surfaces of the connecting fingers. The manner of fabricating the nickel layer on the upper surfaces of the connecting fingers is not specifically limited in the disclosure, and may be selected voluntarily. In some embodiments, the fabrication of the nickel layer on the upper surfaces of the connecting fingers includes: fabricating the nickel layer on the upper surfaces of the connecting fingers by means of electroplating. By fabricating the nickel layer by means of electroplating, thickness uniformity of the nickel layer is good, thereby improving the flatness of the surfaces of the gold layer.

As other feasible implementations, the fabrication of the non-gold conductive layer on the upper surfaces of the connecting fingers includes: fabricating a silver layer on the upper surfaces of the connecting fingers. The manner of fabricating the silver layer on the upper surfaces of the connecting fingers is not specifically limited in the disclosure, and may be selected voluntarily. In some embodiments, the fabrication of the silver layer on the upper surfaces of the connecting fingers includes: fabricating the silver layer on the upper surfaces of the connecting fingers by means of electroplating. By fabricating the silver layer by means of electroplating, thickness uniformity of the silver layer is good, thereby improving the flatness of the surfaces of the gold layer.

It should be noted that when a non-metallic conductive layer is fabricated on the upper surfaces of the connecting fingers, materials of the non-metallic conductive layer are not limited in the disclosure, for example, the material of the non-metallic conductive layer may be indium tin oxide, and the like.

At step S402, the gaps among the connecting fingers on the circuit board are filled with the conductive medium, and a height of the conductive medium is greater than a height of the connecting finger and the non-gold conductive layer.

It should be noted that a difference between the height of the conductive medium and the sum of the heights of the connecting finger and the non-gold conductive layer is not limited in the disclosure. For example, the height difference between the upper surface of the conductive medium and the upper surface of the non-gold conductive layer is 0.514 mil.

In this embodiment, the height difference between the upper surface of the conductive medium and the upper surface of the non-gold conductive layer is the thickness of the gold plated layer. When the height of the conductive medium and the height of the connecting fingers are equal to those in the above embodiments, compared with the above embodiments, the thickness of the gold plated layer decreases in this embodiment. The thickness of the gold plated layer decreases by the thickness of the non-gold conductive layer.

The conductive medium may be the graphite or metal blocks and the like as mentioned in the above embodiments.

At step S403, the tip of the first probe is placed to be tangent to the upper surface of the conductive medium, the tip of the second probe is placed above the connecting fingers, and the tip of the second probe and the tip of the first probe are positioned on the same horizontal plane. The first probe and the second probe are connected to the loop on-off detection device.

The non-gold conductive layer is fabricated on the upper surfaces of the connecting fingers, and thus the tip of the second probe is positioned above the non-gold conductive layer.

In some embodiments, as some feasible implementations, the first probe and the second probe have the same height. However, this is not specifically limited in the disclosure. As other feasible implementations, the first probe and the second probe have unequal heights, for example, the height of the first probe is greater than that of the second probe, or the height of the second probe is greater than that of the first probe. The heights of the first probe and the second probe are lengths of the first probe and the second probe.

In some embodiments, the first probe and the second probe have the same height. In this case, the tip of the first probe and the tip of the second probe may be positioned on the same horizontal plane by controlling ends of the first probe and the second probe away from the tips to be positioned on the same horizontal plane. In this way, the tip of the first probe and the tip of the second probe may be positioned on the same horizontal plane conveniently and quickly without directly detecting positions of the tip of the first probe and the tip of the second probe.

At step S404, gold plating is performed on the upper surface of the non-gold conductive layer, and the gold plating is stopped in response to detecting by the loop on-off detection device that a loop is conducted.

Gold is gradually deposited on the upper surface of the non-gold conductive layer. As the gold plating proceeds, when the upper surface of the gold plated layer is flush with the upper surface of the conductive medium, the tip of the second probe is in contact with the gold plated layer, and the loop is conducted. The thickness for gold plating on all the connecting fingers is equal, which is the height difference between the upper surface of the conductive medium and the upper surface of the non-gold conductive layer, so as to achieve the purpose of controlling the thicknesses of the gold plated layers with high precision.

At step S405, the conductive medium is removed.

The manner of removing the conductive medium depends on the particular conductive medium, and reference may be made to the description of the above embodiments.

Since gold is expensive, if the upper surfaces of the connecting fingers are all plated with gold directly, the amount of gold required is relatively large, resulting in a relatively high cost of the gold plating process for the connecting fingers of the circuit board. In this embodiment, a non-gold conductive layer is fabricated on the upper surface of the connecting finger first, and then the upper surface of the non-gold conductive layer is plated with gold to reduce the thickness of the gold plated layer, thereby reducing the usage amount of the gold material, and reducing the cost.

The manner of gold plating in the disclosure is described in the following embodiment.

At step S501, the gaps among the connecting fingers on the circuit board are filled with the conductive medium, and a height of the conductive medium is greater than the height of the connecting fingers.

The conductive medium may be the graphite or metal blocks and the like as mentioned in the above embodiments.

At step S502, the tip of the first probe is placed to be tangent to the upper surface of the conductive medium, the tip of the second probe is placed above the connecting fingers, and the tip of the second probe and the tip of the first probe are positioned on the same horizontal plane. The first probe and the second probe are connected to the loop on-off detection device.

The first probe and the second probe are respectively connected to the loop on-off detection device via conducting wires. In some embodiments, as some feasible implementations, the first probe and the second probe have the same height. However, this is not specifically limited in the disclosure. As other feasible implementations, the first probe and the second probe have unequal heights, for example, the height of the first probe is greater than that of the second probe, or the height of the second probe is greater than that of the first probe. The heights of the first probe and the second probe are lengths of the first probe and the second probe. In some embodiments, the first probe and the second probe have the same height.

The tip of the first probe is tangential to the upper surface of the conductive medium, in other words, the tip of the first probe is in contact with the upper surface of the conductive medium. The tip of the second probe is placed above the connecting fingers, and positioned on the same horizontal plane with the tip of the first probe. Since the height of the conductive medium is greater than the height of the connecting fingers, a certain distance exists between the tip of the second probe and the upper surfaces of the connecting fingers. The distance between the tip of the second probe and the upper surfaces of the connecting fingers is the height difference between the upper surface of the conductive medium and the upper surfaces of the connecting fingers.

At step S503, gold plating is performed on the upper surfaces of the connecting fingers, and gold plating is stopped in response to detecting that the loop on-off detection device by that a loop is conducted.

In some embodiments, as some specific implementations, the upper surfaces of the connecting fingers are plated with gold by: plating gold on the upper surfaces of the connecting fingers by means of electroplating. However, the manner of gold plating is not specifically limited in the disclosure. As other specific implementations, plating gold on the upper surfaces of the connecting fingers includes: plating gold on the upper surfaces of the connecting fingers by means of chemical plating.

When gold plating is performed by means of electroplating, the circuit board is placed into a gold plating solution, and gold in the gold plating solution may be gradually deposited on the upper surfaces of the connecting fingers by means of electrophoresis, and the thickness gradually increases.

When chemical gold plating is adopted, either cyanide chemical gold plating or non-cyanide chemical gold plating may be used. When the cyanide chemical gold plating is used, in order to obtain a stable chemical gold plating solution, currently a cyanide complex salt is commonly used as the chemical gold plating solution. In order to obtain a relatively high deposition rate of a chemical gold plating process, a solution A and a solution B are prepared. The solution A includes gold potassium cyanide, ethylene diamine tetraacetic acid (EDTA), potassium cyanide, lead dichloride, sodium citrate and hydrazine sulfate, and the solution B includes sodium borohydride and sodium hydroxide. The solution A and the solution B are mixed in a certain ratio, and then heated for plating, wherein lead serves as a depolarizer to increase a plating rate. In order to avoid the influence of the lead on an electronic device, a lead-free gold plating solution may be used, and the lead-free gold plating solution includes gold potassium cyanide, sodium borohydride, potassium cyanide, potassium hydroxide and titanium sulfate, and titanium ions also have the effect of increasing the plating rate. When the non-cyanide chemical gold plating is adopted, the gold plating solution may include sodium gold sulfide, sodium monophosphate, sodium sulfite, 1,2-aminoethane and potassium bromide, or the gold plating solution includes dithiocyano-methane, potassium gold chloride, sodium monophosphate and dimethylaminoborane. Reference may be made to the related art for the specific chemical gold plating process, which will not be described herein.

At step S504, the conductive medium is removed.

Reference may be made to the above embodiments for step S501, step S502, and step S504, which will not be described in detail herein.

In order to enable a worker to timely find the conduction of the first probe and the second probe and stop gold plating, the disclosure further provides another gold plating method for connecting fingers of a circuit board. Referring to FIG. 11, the method includes steps below.

At step S601, gaps among connecting fingers on the circuit board are filled with graphite, and the height of the graphite is greater than the height of the connecting fingers.

At step S602, a tip of a first probe is placed to be tangent to an upper surface of the graphite, a tip of a second probe is placed above the connecting fingers, and the tip of the second probe and the tip of the first probe are positioned on a same horizontal plane. The first probe and the second probe are connected to a loop on-off detection device.

At step S603, gold plating is performed on the upper surfaces of the connecting fingers, and when the loop on-off detection device detects that a loop is conducted, alarm prompt information is sent by the loop on-off detection device and gold plating is stopped.

The alarm prompt information may be audible prompt information and/or flash prompt information.

In the case that the loop on-off detection device does not send the alarm prompt information, the worker needs to continuously observe a pointer on the loop on-off detection device or changes in numerical values on a display screen to timely determine the stopping time of gold plating. It is likely to miss the stopping time of gold plating, namely the time when loop is conducted, and once the time when loop is conducted is missed, the gold plating process continues, so that a final thickness of the gold plated layer may be greater than the thickness required by the gold plated layer, resulting in the waste of gold and an increase in the fabricating cost. However, in this embodiment, the loop on-off detection device may send the alarm prompt information when detecting that the loop is conducted, and may inform the worker immediately, so that the worker timely stops the gold plating process to ensure that the thickness of the gold plated layer is the required thickness.

At step S604, the graphite is removed.

The gold plating method for connecting fingers of a circuit board in the disclosure will be described below in a specific case.

At step 1, upper surfaces of the connecting fingers of the circuit board are plated with copper by means of electroplating, and a thickness of the plated copper is 2.119 mil.

At step 2, the circuit board plated with copper is fixed on an ink jet device, graphite is spayed into gaps among the connecting fingers on the circuit board to achieve mutual conduction between the connecting fingers, and a thickness of the graphite is controlled to be greater than the thickness of the plated copper for 0.514 mil.

At step 3, a first probe and a second probe with the same length are respectively interconnected to an external loop on-off detection device via conducting wires, a tip of the first probe is in contact with an upper surface of the graphite, and a tip of the second probe is controlled to be positioned on a same horizontal plane with the tip of the first probe.

At step 4, the circuit board is placed into a gold plating solution, gold in the gold plating solution may be gradually deposited on surfaces of the connecting fingers plated with copper by means of electrophoresis and the thickness gradually increases. When the thickness of the gold plated layer reaches 0.514 mil, the tip of the second probe is in contact with the gold plated layer on the connecting fingers, and as the connecting fingers and the graphite may be mutually conductive, a conductive path is formed among the second probe→the connecting fingers→the graphite→the first probe→the conducting wire→the loop on-off detection device→the conducting wire→the second probe, and alarm prompt information is sent by the loop on-off detection device to prompt that the thickness for gold plating meets the requirement.

At step 5, the circuit board is taken out of the gold plating solution, the graphite in the gaps among the connecting fingers is rinsed away with water, and the gold plating for the connecting fingers is finished.

The disclosure further provides a circuit board, and connecting fingers on the circuit board are obtained by gold plating treatment by adopting the gold plating method for connecting fingers of a circuit board according to any one of the above embodiments.

The circuit board may be either a hard circuit board or a flexible circuit board, which both fall within the protection scope of the disclosure.

When the connecting fingers on the circuit board in this embodiment are plated with gold, the gaps among the connecting fingers are filled with the conductive medium, so that the connecting fingers are mutually conducted. The conductive medium may be directly removed after the connecting fingers are plated with gold, and lead wires for communicating the connecting fingers do not need to be fabricated. In this way, it is possible to avoid the problems in the related art that burrs and debris are left on edges of the connecting fingers when the lead wires are cut off and the connecting fingers are unsmooth in inserting and pulling due to gold suspension caused by excessive etching, and avoid the problem of residual lead wires. Moreover, as there is no need for fabricating and removing the lead wires, the method of the disclosure may shorten the processing procedure of plating the connecting fingers with gold, and save the process cost. In addition, in the disclosure, when upper surfaces of the connecting fingers are plated with gold, a tip of a first probe is tangent to the upper surface of the conductive medium, a second probe is placed above the connecting fingers, a distance between a tip of the second probe and the upper surfaces of the connecting fingers is a height difference between the conductive medium and the connecting fingers, a loop is formed by the connecting fingers, the conductive medium, the first probe, the second probe and a loop on-off detection device. When the gold plated layer on the upper surfaces of the connecting fingers is in contact with the tip of the second probe, the loop is conducted and the gold plating is finished, so that thicknesses of the gold plated layers on all the connecting fingers are equal, thereby achieving accurate control of the thickness for gold plating, and saving raw materials.

The embodiments described herein are described in a progressive manner, and each embodiment is focused on the differences from the other embodiments. For the same or similar parts between the embodiments, reference can be made to each other. The devices disclosed in the embodiments correspond to the methods disclosed in the embodiments, thus they are described more simply, and the relevant parts can be referred to in the method embodiments.

The above provides a detailed introduction to the gold plating method for the connecting fingers of the circuit board and the circuit board provided by the present disclosure. Specific examples are used herein to explain the principles and implementation methods of the present disclosure. The description of the above embodiments is only used for facilitating understanding the method and core ideas of the present disclosure. It should be pointed out that, for those skilled in the art, various improvements and modifications can also be made to the application without departing from the principles of the application, and these improvements and modifications also fall within the scope of protection of the claims of the present disclosure.

1. A gold plating method for connecting fingers of a circuit board, comprising:
filling gaps among the connecting fingers on the circuit board with a conductive medium, a height of the conductive medium being greater than a height of the connecting fingers;
placing a tip of a first probe to be tangent to an upper surface of the conductive medium, and placing a tip of a second probe above the connecting fingers, wherein the tip of the second probe and the tip of the first probe are positioned on a same horizontal plane, and the first probe and the second probe are connected to a loop on-off detection device;
performing gold plating on upper surfaces of the connecting fingers, and stopping gold plating in response to detecting by the loop on-off detection device that a loop is conducted; and
removing the conductive medium.

2. The gold plating method for connecting fingers of a circuit board according to claim 1, wherein the filling gaps among the connecting fingers on the circuit board with a conductive medium comprises filling the gaps among the connecting fingers on the circuit board with graphite.

3. The gold plating method for connecting fingers of a circuit board according to claim 2, wherein the removing the conductive medium comprises rinsing off the graphite.

4. The gold plating method for connecting fingers of a circuit board according to claim 2, wherein the filling the gaps among the connecting fingers on the circuit board with graphite comprises: filling the gaps among the connecting fingers on the circuit board with the graphite by means of spraying.

5. The gold plating method for connecting fingers of a circuit board according to claim 1, wherein the filling gaps among the connecting fingers on the circuit board with a conductive medium comprises: forming metal blocks in the gaps among the connecting fingers on the circuit board.

6. The gold plating method for connecting fingers of a circuit board according to claim 1, wherein prior to filling the gaps among the connecting fingers on the circuit board with the conductive medium, the method further comprises fabricating a non-gold conductive layer on the upper surfaces of the connecting fingers;
the height of the conductive medium is greater than a sum of the height of the connecting fingers and the height of the non-gold conductive layer.

7. The gold plating method for connecting fingers of a circuit board according to claim 6, wherein the step of performing gold plating on upper surfaces of the connecting fingers, and stopping gold plating in response to detecting by the loop on-off detection device that a loop is conducted comprises:
performing gold plating on an upper surface of then on-gold conductive layer, and stopping gold plating in response to detecting by the loop on-off detection device that the loop is conducted.

8. The gold plating method for connecting fingers of a circuit board according to claim 6, wherein the step of fabricating a non-gold conductive layer on the upper surfaces of the connecting fingers comprises: fabricating a copper layer, a nickel layer or a silver layer on the upper surfaces of the connecting fingers.

9. The gold plating method for connecting fingers of a circuit board according to claim 8, wherein the step of fabricating a copper layer, a nickel layer or a silver layer on the upper surfaces of the connecting fingers comprises:
fabricating the copper layer, the nickel layer or the silver layer on the upper surfaces of the connecting fingers by means of electroplating.

10. The gold plating method for connecting fingers of a circuit board according to claim 6, wherein the step of fabricating a non-gold conductive layer on the upper surfaces of the connecting fingers comprises: fabricating a non-metallic conductive layer on the upper surfaces of the connecting fingers.

11. The gold plating method for connecting fingers of a circuit board according to claim 6, wherein a height difference between the upper surface of the conductive medium and the upper surfaces of the non-gold conductive layer is 0.514 mil.

12. The gold plating method for connecting fingers of a circuit board according to claim 1, wherein the height of the first probe is the same as the height of the second probe.

13. The gold plating method for connecting fingers of a circuit board according to claim 1, wherein the height of the first probe is different from the height of the second probe.

14. The gold plating method for connecting fingers of a circuit board according to claim 13, further comprising:
in response to detecting that the tip of the first probe and the tip of the second probe are not positioned on the same horizontal plane, adjusting a position of the tip of the second probe until the tip of the second probe being adjusted and the tip of the first probe are positioned on the same horizontal plane.

15. The gold plating method for connecting fingers of a circuit board according to claim 1, wherein the step of performing gold plating on upper surfaces of the connecting fingers comprises: performing gold plating on the upper surfaces of the connecting fingers by means of electroplating.

16. The gold plating method for connecting fingers of a circuit board according to claim 15, wherein the step of performing gold plating on the upper surfaces of the connecting fingers by means of electroplating comprises:
placing the circuit board into a gold plating solution, and depositing gold in the gold plating solution on the upper surfaces of the connecting fingers by means of electrophoresis.

17. The gold plating method for connecting fingers of a circuit board according to claim 1, wherein the step of performing gold plating on upper surfaces of the connecting fingers comprises: performing gold plating on the upper surfaces of the connecting fingers by means of chemical plating.

18. The gold plating method for connecting fingers of a circuit board according to claim 1, wherein the circuit board comprises a plurality of connecting fingers with equal or unequal lengths.

19. The gold plating method for connecting fingers of a circuit board according to claim 1, in response to detecting by the loop on-off detection device that the loop is conducted, the method further comprises:
sending alarm prompt information by the loop on-off detection device.

20. A circuit board, wherein connecting fingers on the circuit board are gold plated by adopting the gold plating method for connecting fingers claim 1.
